(19) United States
(12) Patent Application Publication
(10) Pub. No.: US 2026/0343744 A1
(43) Pub. Date: Oct. 29, 2026

(54) PRINTED CIRCUIT BOARD, MANUFACTURING METHOD THEREOF, AND ELECTRONIC COMPONENT PACKAGE INCLUDING THE SAME

(71) Applicant: SAMSUNG ELECTRO-MECHANICS CO., LTD., Suwon-si (KR)

(72) Inventors: Young Kuk Ko, Suwon-si (KR); Sanghoon Kim, Suwon-si (KR); Gyumook Kim, Suwon-si (KR); Taehun Kim, Suwon-si (KR)

(73) Assignee: SAMSUNG ELECTRO-MECHANICS CO., LTD., Suwon-si (KR)

(21) Appl. No.: 19/381,861

(22) Filed: Nov. 6, 2025

(30) Foreign Application Priority Data
Apr. 28, 2025 (KR) 10-2025-0055369
Jul. 30, 2025 (KR) 10-2025-0104323

(51) Int. Cl. H05K 1/11; H05K 3/40; H05K 3/42

(52) U.S. Cl. CPC H05K 1/116; H05K 3/4007; H05K 3/42; H05K 2201/2081

(57) ABSTRACT

A printed circuit board according to an embodiment of the present disclosure may include an insulating layer, a first pad disposed at the insulating layer, a second pad disposed at the insulating layer and spaced apart from the first pad, a protruding pattern disposed on an upper surface of the first pad, and a solder resist layer disposed on an upper surface of the insulating layer and comprising a first opening exposing the protruding pattern and a second opening exposing at least a portion of the second pad. The solder resist layer may include a wall pattern spaced apart from the protruding pattern and surrounding a side surface of the protruding pattern.

### CROSS-REFERENCE TO RELATED APPLICATION

This application claims priority to and the benefit of Korean Patent Application No. 10-2025-0055369 filed with the Korean Intellectual Property Office on Apr. 28, 2025, and Korean Patent Application No. 10-2025-0104323 filed with the Korean Intellectual Property Office on Jul. 30, 2025, the entire contents of which are incorporated herein by reference.

### BACKGROUND

The present disclosure relates to a printed circuit board, a manufacturing method thereof, and an electronic component package including the same.

A printed circuit board may be used as a board for mounting electronic components.

With the recent development of 3G, 4G, 5G, and more high-speed communication and artificial intelligence (AI) technologies, highly integrated printed circuit board that implements related electronic components can be used. The electronic components may include a semiconductor chip, an antenna, an inductor, a capacitor, a filter, and the like. For example, a plurality of the electronic components are mounted on a single printed circuit board, so that various and complex product functions can be implemented while reducing the mounting space, thereby miniaturizing and thinning the printed circuit board.

As the printed circuit board is miniaturized and thinned as described above, warpage and/or distortion of the printed circuit board may occur. Since printed circuit boards are recently used in fields that require a high level of reliability, it is necessary to provide printed circuit boards with improved structural stability and reliability while miniaturizing and thinning, a manufacturing method thereof, and an electronic component package including the same.

### SUMMARY

An embodiment of the present disclosure attempts to provide a printed circuit board with improved reliability.

Another embodiment of the present disclosure attempts to provide a manufacturing method of a printed circuit board with improved reliability.

Another embodiment of the present disclosure attempts to provide an electronic component package with improved reliability.

A printed circuit board according to an embodiment of the present disclosure may include an insulating layer, a first pad disposed at the insulating layer, a second pad disposed at the insulating layer and spaced apart from the first pad, a protruding pattern disposed on an upper surface of the first pad, and a solder resist layer disposed on an upper surface of the insulating layer and including a first opening exposing the protruding pattern and a second opening exposing at least a portion of the second pad. The solder resist layer may include a wall pattern spaced apart from the protruding pattern and surrounding a side surface of the protruding pattern.

A length from the upper surface of the insulating layer to an upper surface of the wall pattern in a thickness direction perpendicular to the upper surface of the insulating layer may be equal to or greater than a length from the upper surface of the insulating layer to an upper surface of the protruding pattern.

A side surface of the first pad and a side surface of the second pad may be respectively disposed on the upper surface of the insulating layer.

A side surface of the first pad and a side surface of the second pad may be respectively embedded in the insulating layer, and at least a portion of the upper surface of the first pad and at least a portion of an upper surface of the second pad may not be embedded in the insulating layer.

A length from the upper surface of the insulating layer to an upper surface of the protruding pattern in a thickness direction perpendicular to the upper surface of the insulating layer may be greater than a length from the upper surface of the insulating layer to an upper surface of the second pad.

The wall pattern may surround a plurality of the protruding patterns together.

A width of the protruding pattern may be smaller than that of the first pad.

The printed circuit board may further include a plurality of sub-insulating layers included in the insulating layer, circuit wirings and connection pads disposed between the plurality of sub-insulating layers, and a via penetrating at least a portion of the plurality of sub-insulating layers to be connected to the connection pads.

The first pad and the second pad may be respectively connected to the connection pads and the circuit wirings through the via.

A manufacturing method of a printed circuit board according to an embodiment of the present disclosure may include forming a build-up structure including an insulating layer and circuit wirings and connection pads disposed on the insulating layer on a carrier substrate, separating the build-up structure from the carrier substrate, forming a first pad at the insulating layer, a second pad disposed at the insulating layer and spaced apart from the first pad, and a protruding pattern disposed on the first pad, and forming a solder resist layer including a first opening exposing the protruding pattern, a second opening exposing at least a portion of the second pad, and pattern spaced apart from the protruding pattern and surrounding a side surface of the protruding pattern on an upper surface of the insulating layer.

Forming of the first pad and the second pad may include forming via holes in the insulating layer, and forming the first pad, the second pad, and vias connecting the first pad and the second pad to the connection pads, respectively, through a plating process in the via holes.

The protruding pattern may be formed on the first pad through a plating process.

Forming of the solder resist layer may include applying a solder resist on the upper surface of the insulating layer, first thinning the solder resist to form the first opening and the wall pattern, and second thinning the solder resist to form the solder resist layer including the second opening.

Forming of the solder resist layer may include forming a first solder resist layer including the second opening, and forming a second solder resist layer including the wall pattern and the first opening on the first solder resist layer.

Forming of the first pad and the second pad may further include forming a via connecting the first pad and the second pad to the circuit wirings respectively.

An electronic component package according to an embodiment of the present disclosure may include the printed circuit board described above, a first electronic component connecting to the protruding pattern, and a second electronic component connecting to the second pad.

A ratio of a length from the upper surface of the insulating layer to an upper surface of the second electronic component in the thickness direction to a length from the upper surface of the insulating layer to an upper surface of the first electronic component in a thickness direction may be 0.9 to 1.1.

According to an embodiment of the present disclosure, a step difference between electronic components may be substantially removed or significantly reduced. Accordingly, warpage and/or distortion of a printed circuit board may be suppressed, and structural stability and reliability of an electronic component package may be improved.

According to an embodiment of the present disclosure, in the soldering process for mounting an electronic component, a solder short in which a metal component is in contact with an adjacent pad or circuit may be prevented, and the driving reliability of a printed circuit board and the stability of an electronic component package may be improved.

However, the problems to be solved by the embodiments are not limited to those described above, and can be variously extended within the scope of the technical ideas included in the embodiments.

### BRIEF DESCRIPTION OF THE DRAWINGS

FIG. 1 is a perspective view illustrating a printed circuit board according to an embodiment.

FIG. 2 is a cross-sectional view of the printed circuit board taken along line I-I' of FIG. 1.

FIGS. 3-7 are partially enlarged plan views of an area corresponding to an area A of FIG. 1 on a upper surface of a printed circuit board according to another embodiments.

FIGS. 8-16 are cross-sectional views illustrating a manufacturing method of a printed circuit board according to an embodiment.

FIGS. 17-20 are cross-sectional views illustrating a manufacturing method of a printed circuit board according to another embodiment.

FIG. 21 is a cross-sectional view illustrating a printed circuit board according to another embodiment.

FIG. 22 is a cross-sectional view illustrating an electronic component package according to an embodiment.

FIG. 23 is a cross-sectional view illustrating an electronic component package according to another embodiment.

### DETAILED DESCRIPTION OF THE EMBODIMENTS

Hereinafter, various embodiments of the present disclosure will be described in detail so that a person of ordinary skill in the technical field to which the present disclosure belongs can easily implement it with reference to the accompanying drawings. In order to clearly describe the present disclosure, parts unrelated to the description are omitted in the drawings, and the same reference numerals are designated to the same or similar elements throughout the specification. In addition, some components in the drawings may be exaggerated, omitted, or schematically illustrated, and the size of each component may not entirely reflect the actual size.

The accompanying drawings are provided only in order to allow embodiments disclosed in the present specification to be easily understood and are not to be interpreted as limiting the concept disclosed in the present specification, and it is to be understood that the present disclosure includes all modifications, equivalents, and substitutions without departing from the scope and concept of the present disclosure.

Terms including ordinal numbers such as first, second, and the like will be used only to describe various components and are not to be interpreted as limiting these components. The terms are only used to differentiate one component from other components.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Furthermore, in the specification, the word “on” or “above” means positioned on or below the object portion, and does not necessarily mean positioned on the upper side of the object portion based on a gravitational direction.

It will be further understood that terms "comprises/includes” or “have” used throughout the specification specify the presence of stated features, numerals, steps, operations, components, parts, or a combination thereof, but do not preclude the presence or addition of one or more other features, numerals, steps, operations, components, parts, or a combination thereof. Accordingly, unless explicitly described to the contrary, the word “comprise” and variations such as “comprises” or “comprising” will be understood to imply the inclusion of stated components but not the exclusion of any other components.

Furthermore, throughout the specification, the phrase “in a plan view” means when an object portion is viewed from above, and the phrase “in a cross-sectional view” means when a cross-section taken by vertically cutting an object portion is viewed from the side.

In addition, throughout the specification, "connected" means that two or more components are not only directly connected, but two or more components may be connected indirectly through other components, physically connected as well as being electrically connected, or it may be referred to by different names depending on the location or function but may mean integral.

Hereinafter, embodiments will be described with reference to the drawings.

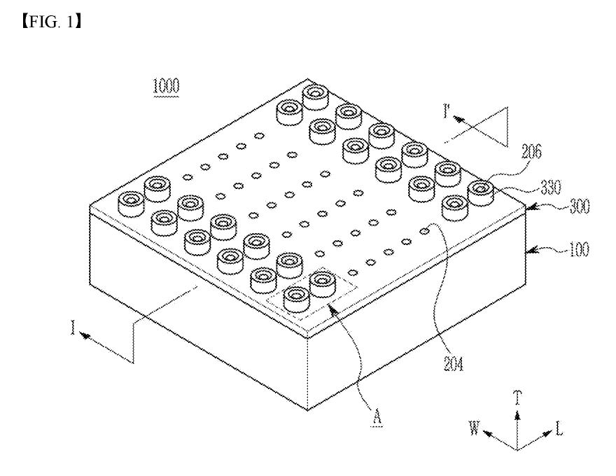

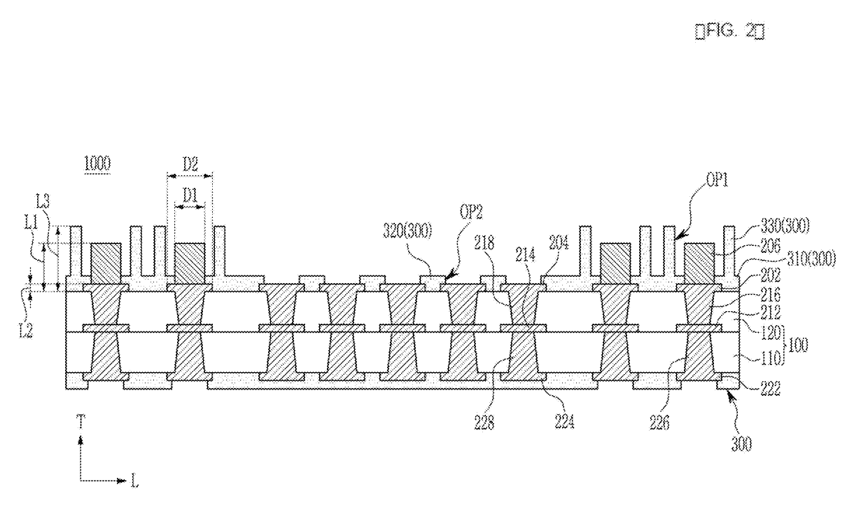

FIG. 1 is a perspective view illustrating a printed circuit board according to an embodiment. FIG. 2 is a cross-sectional view of the printed circuit board taken along line I-I' of FIG. 1.

The L-axis, W-axis, and T-axis shown in the drawings respectively indicate the length direction, width direction, and thickness direction of the printed circuit board and an insulating layer 100.

The thickness direction (T-axis direction) may indicate a direction substantially perpendicular to an upper surface of the insulating layer 100. For example, the thickness direction may indicate a direction in which a first sub-insulating layer 110 and a second sub-insulating layer 120 included in the insulating layer 100 are stacked.

The length direction (L-axis direction) and the width direction (W-axis direction) may be parallel to the upper surface of the insulating layer 100, respectively. The length direction and the width direction may be approximately perpendicular to each other on a plane parallel to the upper surface of the insulating layer 100, and may be approximately perpendicular to the thickness direction, respectively. In an example, the length of the printed circuit board 1000 or the insulating layer 100 in the length direction may be greater than the length in the width direction.

Referring to FIGS. 1 and 2, the printed circuit board 1000 according to an embodiment, may include an insulating layer 100, a first pad 202 disposed on the insulating layer 100, a second pad 204 disposed on the insulating layer 100 and spaced apart from the first pad 202, a protruding pattern 206 disposed on an upper surface of the first pad 202, and a solder resist layer 300 disposed on the upper surface of the insulating layer 100 and exposing at least a portion of the first pad 202, the protruding pattern 206, and at least a portion of the second pad 204.

The first pad 202 and the second pad 204 may be disposed on the same layer or at the same level.

At least a portion of the upper surface of the first pad 202 and at least a portion of an upper surface of the second pad 204 may be exposed on the upper surface of the insulating layer 100.

The insulating layer 100 may include a plurality of sub-insulating layers 110 and 120. In an example, the insulating layer 100 may include a first sub-insulating layer 110 and the second sub-insulating layer 120 that are sequentially stacked.

The printed circuit board 1000 may further include circuit wirings (not shown) and connection pads 212 and 214 disposed between a plurality of the sub-insulating layers 110 and 120, and vias 216, 218, 226, and 228 penetrating at least some of the plurality of the sub-insulating layers 110 and 120 and connected to the connection pads 212 and 214.

In an example, the first via 216 may penetrate the second sub-insulating layer 120 and may electrically connect the first pad 202 to the first connection pad 212. The second via 218 may penetrate the second sub-insulating layer 120, and may electrically connect the second pad 204 and the second connection pad 214.

The printed circuit board 1000 may include the upper surface and a lower surface facing the upper surface.

The printed circuit board 1000 may further include lower pads 222 and 224 disposed on a lower surface of the insulating layer 100.

In an example, the third via 226 may penetrate the first sub-insulating layer 110, and the first lower pad 222 and the first connection pad 212 may be electrically connected to each other by the third via 226. The fourth via 228 may penetrate the first sub-insulating layer 110, and may electrically connect the second lower pad 224 to the second connection pad 214.

The pads 202, 204, 212, 214, 222, 222 and 224 on different sub-insulating layers 110 and 120 may be connected through the vias 216, 218, 226, and 228. In an example, the protruding pattern 206, the first pad 202, the first via 216, the first connection pad 212, the third via 226, and the first lower pad 222 may be electrically connected in the thickness direction. In an example, the second pad 204, the second via 218, the second connection pad 214, the fourth via 228, and the second lower pad 224 may be electrically connected in the thickness direction.

A fine circuit pattern may be implemented by the circuit wirings (not shown) disposed on each of the sub-insulating layers 110 and 120. One end of the circuit wirings disposed on each of the sub-insulating layers 110 and 120 may be provided as the pads 202, 204, 212, 214, 222, and 224 described above.

The insulating layer 100 may include an Ajinomoto Build-up Film (ABF). In an example, at least one of the sub-insulating layers 110 and 120 may include a prepreg manufactured by impregnating glass fibers with a thermosetting resin or a thermoplastic resin. In another example, at least one of the sub-insulating layers 110 and 120 may include a Photo-Imageable Dielectric (PID).

Although FIG. 2 illustrates that the insulating layer 100 includes two sub-insulating layers 110 and 120, three or more sub-insulating layers may be included depending on the design of the printed circuit board. In this case, circuit wirings and pads may also be disposed on each sub-insulating layer, and there may be more vias that penetrate the sub-insulating layers and connect pads or circuit wirings on different sub-insulating layers.

In an example, the upper surface of the insulating layer 100 to which the first pad 202 and the second pad 204 are exposed may be a surface facing an electronic component, and the lower surface of the insulating layer 100 to which the first lower pad 222 and the second lower pad 224 are exposed may be a surface facing a mother board on which an electronic component package is mounted.

The protruding pattern 206 may be positioned on an upper surface of the first pad 202 and may extend in the thickness direction (T-axis direction). In the thickness direction, a length L1 from the upper surface of the insulating layer 100 to an upper surface of the protruding pattern 206 may be greater than a length L2 from the upper surface of the insulating layer 100 to the upper surface of the second pad 204.

Through the protruding pattern 206, an electronic component with a relatively small thickness is mounted on the protruding pattern 206, and an electronic component with a relatively large thickness is mounted on the second pad 204, so that the step difference between the electronic components may be substantially removed or significantly reduced. Accordingly, warpage and/or distortion of a printed circuit board may be suppressed, and structural stability and reliability of an electronic component package may be improved. The thickness of the electronic component may indicate a length of the electronic component in the thickness direction.

The protruding pattern 206 may have a bar shape or a pillar shape extending in the thickness direction.

The protruding pattern 206 may be made of substantially the same material as or may include the same material as the first pad 202. For example, the protruding pattern 206 may be provided as a terminal post, a pad bump, or the like disposed on the first pad 202.

In an example, a width D1 of the protruding pattern 206 may be less than a width D2 of the first pad 202. Accordingly, the protruding pattern 206 may be stably disposed on the first pad 202 so that reliability and stability of a printed circuit pattern may be further improved.

The width D1 of the protruding pattern 206 may represent the length of the longest line segment among line segments connecting two points located around the upper surface of the protruding pattern 206 and passing through the center point of the upper surface of the protruding pattern 206. When the upper surface of the protruding pattern 206 is circular, the width D1 of the protruding pattern 206 may represent a diameter of a circle. When the upper surface of the protruding pattern 206 is elliptical, the width D1 of the protruding pattern 206 may represent a length of a major axis passing through the center point of the ellipse. When the upper surface of the protruding pattern 206 is a polygon, the width D1 of the protruding pattern 206 may represent a length of the longest diagonal among the diagonal lines passing through the center point of the polygon.

The width D2 of the first pad 202 may represent the length of the longest line segment among line segments connecting two points located around the upper surface of the first pad 202 and passing through the center point of the upper surface of the first pad 202. When the upper surface of the first pad 202 is circular, the width D2 of the first pad 202 may represent a diameter of a circle. When the upper surface of the first pad 202 is elliptical, the width D2 of the first pad 202 may represent a length of a long axis passing through the center point of the ellipse. When the upper surface of the first pad 202 is a polygon, the width D2 of the first pad 202 may represent a length of the longest diagonal among the diagonal lines passing through the center point of the polygon.

The width D1 of the protruding pattern 206 may be measured from a scanning electron microscope (SEM) analysis image obtained by photographing the printed circuit board 1000 in the thickness direction on the upper surface of the printed circuit board 1000. The width D1 according to the above-described definition of the protruding pattern 206 may be measured in the SEM analysis image. When the printed circuit board 1000 includes a plurality of protruding patterns 206, the width D1 of the protruding pattern 206 may be obtained by measuring the widths according to the above-described definition of the plurality of protruding patterns 206, respectively, and averaging the measured widths.

The width D2 of the first pad 202 may be measured from the SEM analysis image obtained by polishing the upper surface of the printed circuit board 1000 in the thickness direction so that the entire upper surface of the first pad 202 is exposed, and photographing the printed circuit board 1000 on the upper surface of the printed circuit board 1000 in the thickness direction. The width D2 according to the above-described definition of the first pad 202 may be measured in the SEM analysis image. When the printed circuit board 1000 includes a plurality of first pads 202, the width D2 of the first pad 202 may be obtained by measuring the widths according to the above-described definition of the plurality of first pads 202, respectively, and averaging the measured widths.

The protruding pattern 206 may be directly disposed on the upper surface of the first pad 202. The protruding pattern 206 may be in direct contact with the upper surface of the first pad 202. Accordingly, the protruding pattern 206 may be provided as the external connection terminal together with the first pad 202.

The pads 202, 204, 212, 214, 222, and 224, the circuit wirings, vias 216, and 228, and the protruding patterns 206 may include at least one selected from the group consisting of copper (Cu), aluminum (Al), silver (Ag), tin (Sn), gold (Au), nickel (Ni), lead (Pb), titanium (Ti), alloys thereof, and the like. These may be used alone or in combination of two or more. In an example, the pads 202, 204, 212, 214, 222, and 224, the circuit wirings, the vias 216, 226, and 228, and the protruding pattern 206 may include copper (Cu). Accordingly, while electrical conductivity is improved, processability can be enhanced.

The solder resist layer 300 may be disposed on the upper surface of the insulating layer 100 of the printed circuit board 1000 according to the present disclosure. The solder resist layer 300 may also be disposed on the lower surface of the insulating layer 100.

The solder resist layer 300 may include a first opening OP1 exposing the protruding pattern 206 and a second opening OP2 exposing at least a portion of the second pad 204.

The solder resist layer 300 may include a first portion 310 constituting the first opening OP1 and adjacent to the first pad 202 and the protruding pattern 206, and a second portion 320 constituting the second opening OP2 and adjacent to the second pad 204. The first portion 310 and the second portion 320 may be directly disposed on the upper surface of the insulating layer 100. The first portion 310 and the second portion 320 may be formed at substantially the same layer or level.

In the printed circuit board 1000 according to an example of the present disclosure, the solder resist layer 300 may include a wall pattern 330 spaced apart from the protruding pattern 206 and surrounding a side surface of the protruding pattern 206. Accordingly, solder short in contact with adjacent pads or circuits can be prevented in the soldering process for mounting electronic components, and the driving reliability of the printed circuit board 1000 and the stability of the electronic component package can be improved.

The wall pattern 330 extends on the first portion 310 in the thickness direction, and may protrude and extend in the same direction as the protruding pattern 206.

The wall pattern 330 may be spaced apart from the protruding pattern 206 in the longitudinal direction (L-axis direction) and/or the width direction (W-axis direction). Accordingly, a bump for connection with the electronic component may sufficiently contact the protruding pattern.

In the thickness direction, a length L3 from the upper surface of the insulating layer 100 to an upper surface of the wall pattern 330 may be greater than or equal to the length L1 from the upper surface of the insulating layer 100 to the upper surface of the protruding pattern 206. In one example, L3 may be greater than L1. Accordingly, solder short circuits are further suppressed and the connection stability of the electronic component and the printed circuit board 1000 is improved, thereby further improving the structural stability and reliability of the printed circuit board 1000 and the electronic component package.

The solder resist layer 300 may include a known solder resist material, a material including a thermosetting resin, and/or an inorganic filler. These may be used alone or in combination of two or more.

In FIG. 1, the shape of the protruding pattern 206 and the shape of the wall pattern 330 are illustrated in a cylindrical shape and a hollow cylindrical shape, respectively, but the shape of the protruding pattern 206 and the shape of the wall pattern 330 may be modified into a polygon or an elliptical shape depending on the design of the printed circuit board 1000.

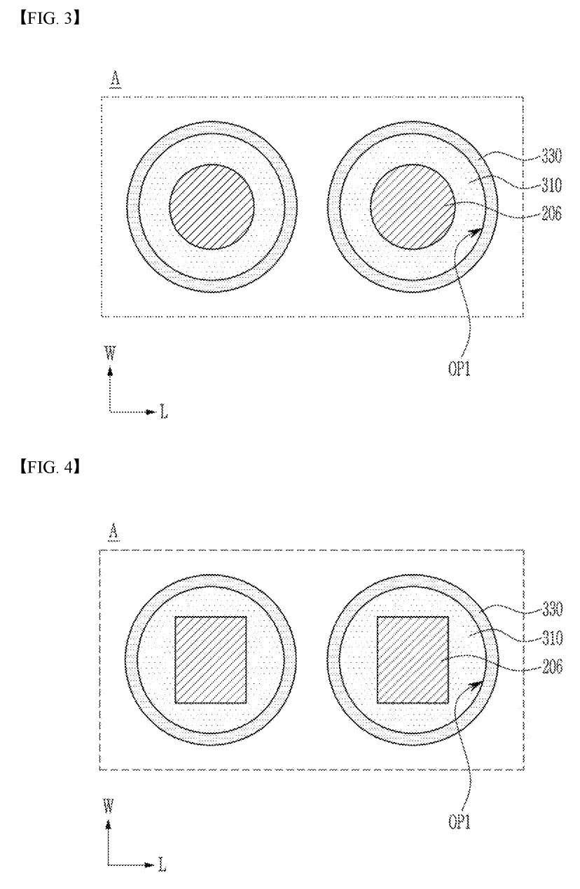

FIGS. 3-7 are partially enlarged plan views of an area corresponding to an area A of FIG. 1 on a upper surface of a printed circuit board according to another embodiments. Specifically, FIG. 3 is a partially enlarged plan view of the area corresponding to the area A of FIGS. 1, and 4-7 are partially enlarged plan views of the area corresponding to the area A of FIG. 1 in another examples of the printed circuit board 1000 observed on the upper surface of the printed circuit board 1000.

As illustrated in FIGS. 3-6, the upper surface of the protruding pattern 206 and the upper surface of the wall pattern 330 observed in the direction perpendicular to the plane, for example the upper surface of the insulating layer 100, in the longitudinal direction and the width direction may include a polygon including a circle and a square.

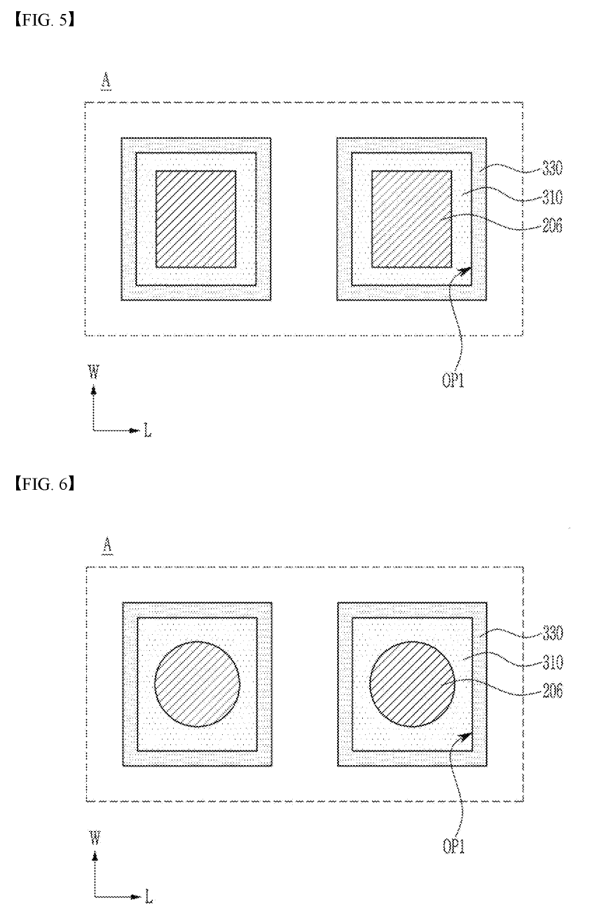

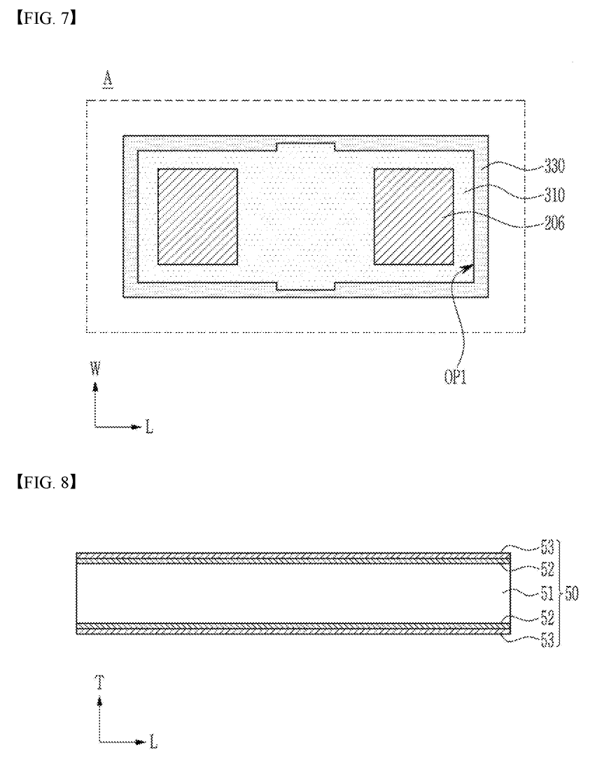

The upper surface of the protruding pattern 206 and the upper surface of the wall pattern 330 may all be circular as illustrated in FIG. 3, may all be rectangular as illustrated in FIG. 5, and may have different shapes as illustrated in FIGS. 4 and 6.

Referring to FIG. 7, the wall pattern 330 may surround a plurality of protruding patterns 206 together. As illustrated in FIG. 7, one wall pattern 330 may surround two or more protruding patterns 206 together. In this case, an gap between the first pads 202 may be relatively narrow, and thus space utilization may be further improved.

The shapes of the upper surface of the protruding pattern 206 and the upper surface of the wall pattern 330 are not limited to the shapes illustrated in FIGS. 3-7, and may be changed according to the design of the printed circuit board 1000.

Hereinafter, a manufacturing method of the printed circuit board 1000 described above with reference to the drawings will be described in detail.

FIGS. 8-16 are cross-sectional views illustrating a manufacturing method of a printed circuit board according to an embodiment.

Referring to FIG. 8, a carrier substrate 50 may be prepared.

The carrier substrate 50 may include a core 51, a release layer 52 disposed on one or both surfaces of the core 51, and a seed metal layer 53 disposed on the release layer 52.

The core 51 may be a Detached Carrier Film and may include, for example, Copper Clad Laminate (CCL) and the like. In this case, the core 51 may include a core layer containing a prepreg manufactured by impregnating glass fibers with thermosetting resin or thermoplastic resin, and a copper foil layer formed on one or both sides of the core layer above. The release layer 52 may be disposed on the copper foil layer.

The release layer 52 may be formed using a known material for easy separation of the carrier board 50 and the printed circuit board.

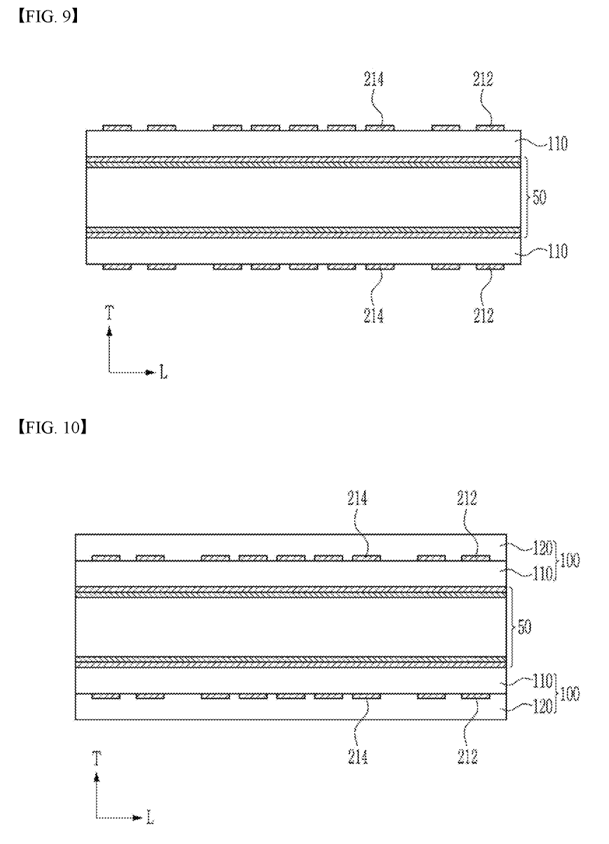

Referring to FIG. 9, the first sub-insulating layer 110 may be formed on the seed metal layer 53.

Circuit wirings (not shown), and a first connection pad 212 and a second connection pad 214 connected to one end of the circuit wirings, respectively, may be formed on the first sub-insulating layer 110.

Referring to FIG. 10, the second sub-insulation layer 120 may be formed on the first-sub insulating layer 110 and the connection pads 212 and 214.

Each of the first sub-insulating layer 110 and the second sub-insulating layer 120 may include the same type of material as the material of the insulating layer 100 described above. For example, the first sub-insulating layer 110 and the second sub-insulating layer 120 may be formed by applying and curing the same kind of material as the material of the insulating layer 100 described above.

In an example, a copper foil layer (not shown) may be disposed on the second sub-insulating layer 120. The copper foil layer may include a seed copper foil layer for forming the first pad 202 and the second pad 204, a carrier copper foil layer for transport, and/or a release layer disposed between the seed metal layer and the carrier copper foil layer.

For convenience of description, in the present disclosure, a stack structure of the seed metal layer 53, the insulating layer 100 including the sub-insulating layers 110 and 120, circuit wiring layers and the connection pads 212 and 214, and a barrier layer 130 may be defined as the build-up structure.

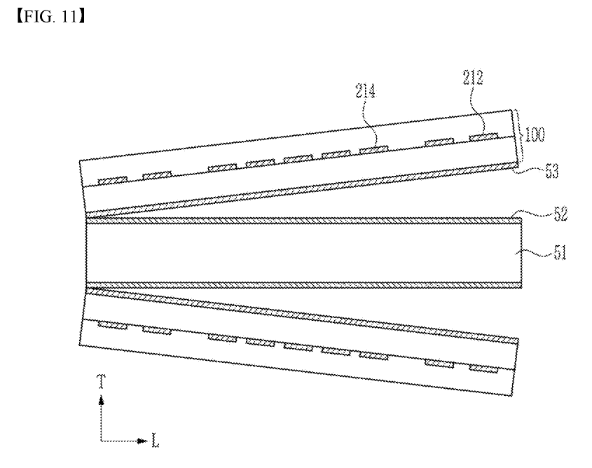

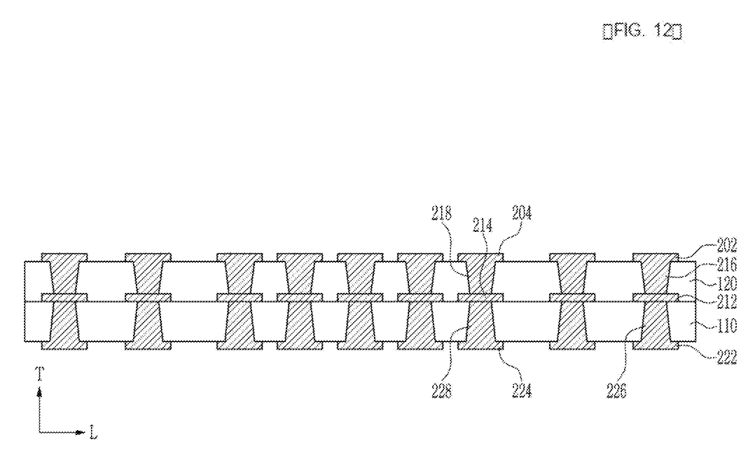

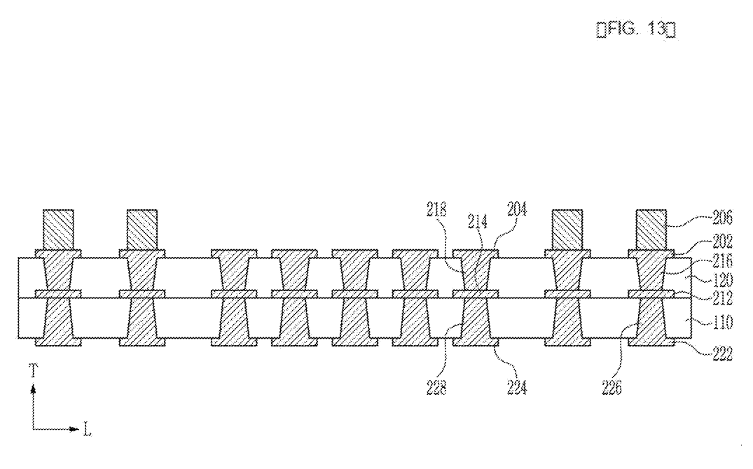

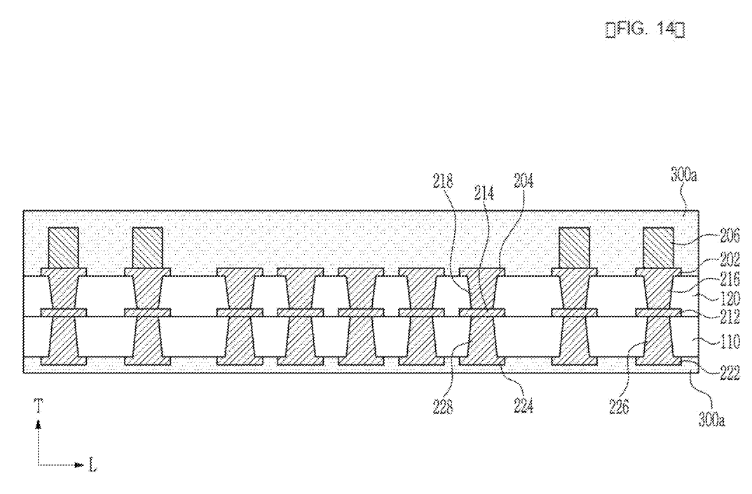

Referring to FIG. 11, the build-up structure may be separated from the carrier substrate 50 by separating the release layer 52 and the seed metal layer 53.

Referring to FIG. 12, via holes may be formed in each of the sub-insulating layers 110 and 120 so that the connection pads 212 and 214 are exposed, and the first pad 202, the second pad 204, the first lower pad 222, the second lower pad 224, the first via 216, the second via 218, the third via 226, and the fourth via 228 may be formed by plating the via holes.

According to an example, the via holes penetrating each of the sub-insulating layers 110 and 120 through a drill or laser may be formed. The first pad 202, the second pad 204, the first lower pad 222, the second lower pad 224, the first via 216, the second via 218, the third via 226, and the fourth via 228 connected to the connection pads 212 and 214 may be plated from the inside of the via holes.

The connection pads 212 and 214, the first pad 202, the second pad 204, the first lower pad 222, the second lower pad 224, the first via 216, the second via 218, the third via 226, and the fourth via 228 described above may be formed through a wiring formation process such as an Additive Process (AP), a Semi AP (SAP), a Modified SAP (MSAP), a Tenting (TT) and the like. These may be used alone or in combination of two or more.

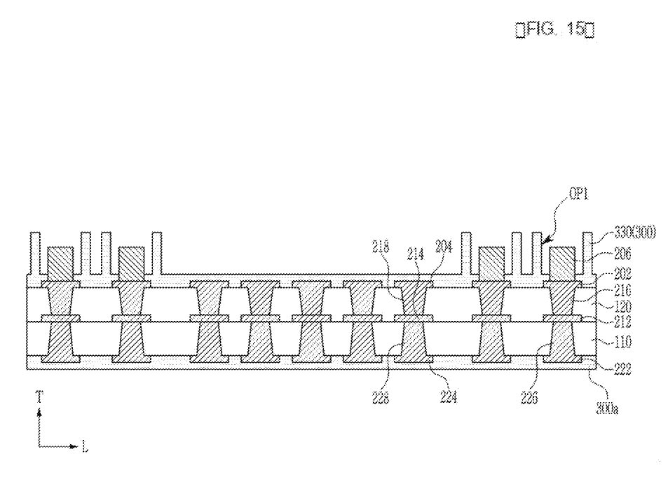

Referring to FIG. 13, the protruding pattern 206 may be formed on the first pad 202. For example, the protruding pattern 206 may be formed on the first pad 202 through a plating process.

In an example, the protruding pattern 206 may be plated through a separate process from the first pad 202.

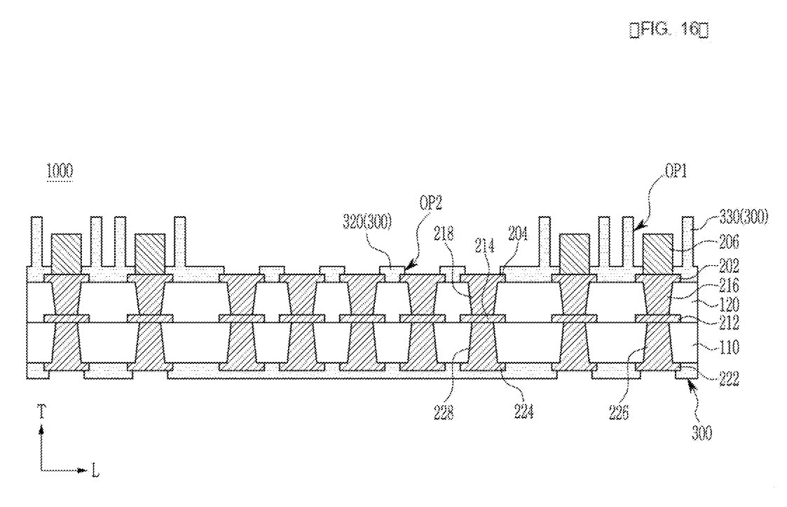

Referring to FIG. 14, a solder resist 300a may be applied on the upper surface and the lower surface of the insulating layer 100.

The solder resist 300a may include, for example, a photosensitive resin.

The solder resist 300a may be applied on the upper surface of the insulating layer 100 to cover the first pad 202, the protruding pattern 206, and the second pad 204. The solder resist 300a may be applied on the lower surface of the insulating layer 100 to cover the first lower pad 222 and the second lower pad 224.

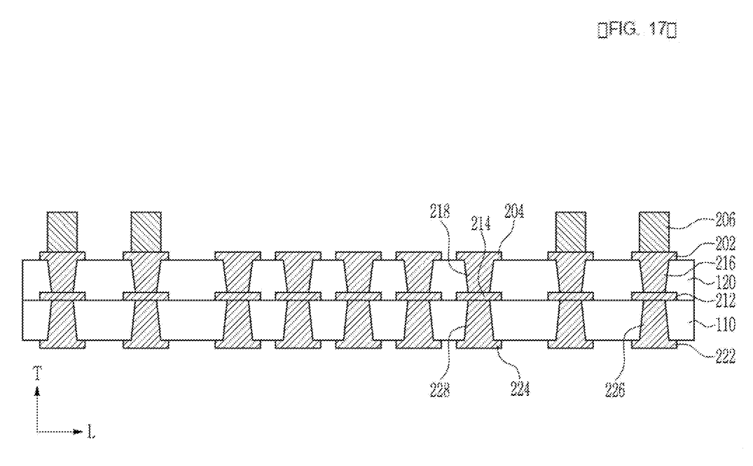

Referring to FIG. 15, the first opening OP1 exposing the protruding pattern 206 by first thinning the solder resist 300a and the wall pattern 330 spaced apart from the protruding pattern 206 and surrounding the side surface of the protruding pattern 206 may be formed.

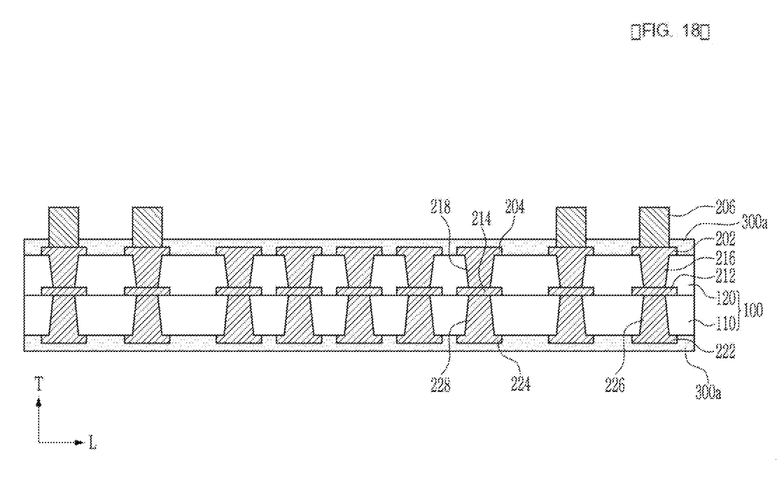

Referring to FIG. 16, the solder resist layer 300 including the second opening OP2 exposing the second pad 204 may be formed by second thinning the solder resist 300a.

The first thinning and the second thinning may be performed by chemical etching. For example, the degree/thickness of the solder resist 300a can be controlled by controlling the reactivity of the known solder resist etchant in the first and second thinning.

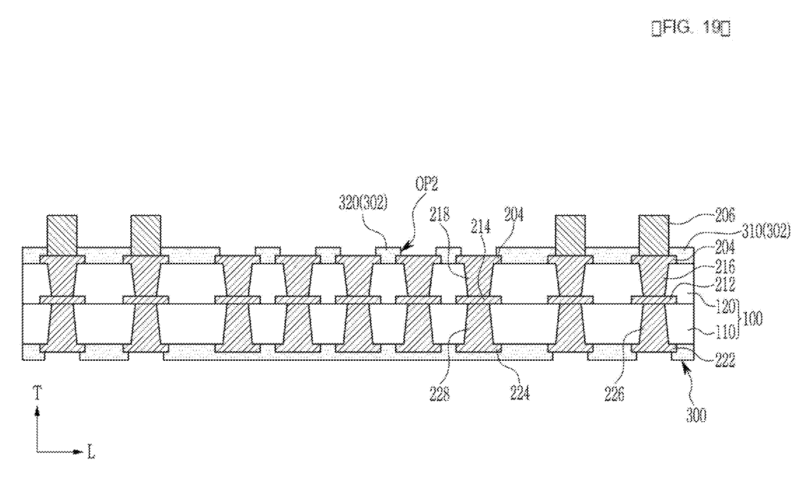

FIGS. 17-20 are cross-sectional views illustrating a manufacturing method of the printed circuit board 1000 according to another embodiment. Specifically, FIGS. 17-20 illustrate a manufacturing method of an example in which the solder resist layer 300 is formed using a method different from the method of forming the solder resist layer 300 described with reference to FIGS. 13-16.

The printed circuit board 1000 illustrated in FIG. 17 may be manufactured in the same manner as the manufacturing method described with reference to FIGS. 8-13.

Referring to FIG. 18, the solder resist 300a may be applied on the upper surface and the lower surface of the insulating layer 100. As illustrated in FIG. 18, the solder resist 300a may be applied to cover the first pad 202 and the second pad 204 and expose the protruding pattern 206.

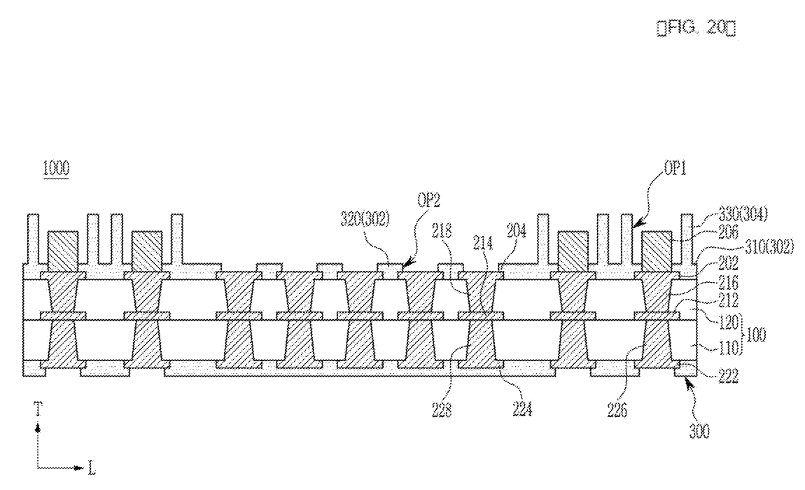

Referring to FIG. 19, a first solder resist layer 302 including the second opening OP2 exposing the second pads 204 may be formed by patterning the solder resist 300a through a photolithography process. The first solder resist layer 302 may include the above-described the first portion 310 and the second portion 320 of the solder resist layer 300.

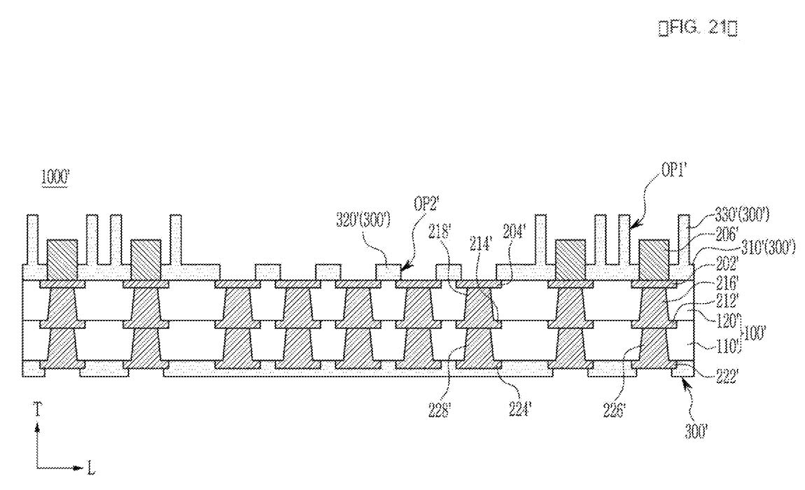

Referring to FIG. 20, a second solder resist layer 304 including the first opening OP1 exposing the above-described the wall pattern 330 and the protruding pattern 206 may be formed on the first solder resist layer 302. The second solder resist layer 304 may substantially be the wall pattern 330. The second solder resist layer 304 may be formed by performing a photolithography process after the solder resist is applied.

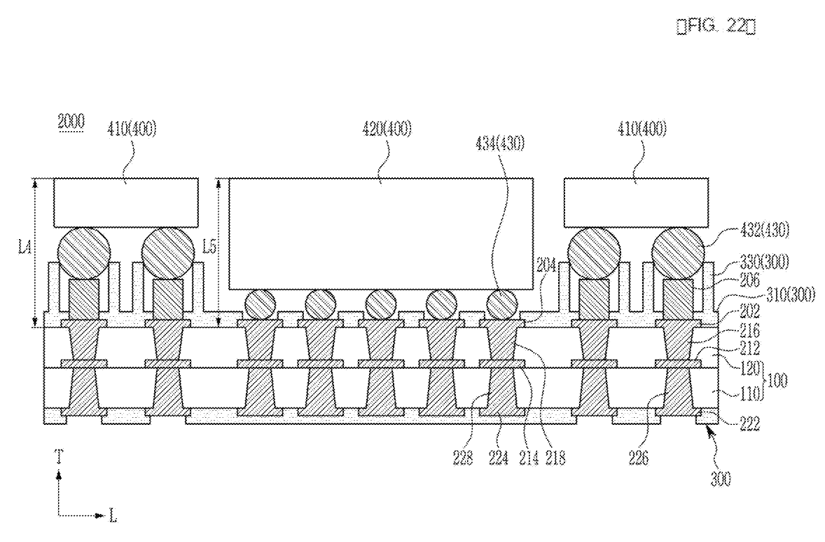

FIG. 21 is a cross-sectional view illustrating a printed circuit board according to another embodiment. Specifically, FIG. 21 is a cross-sectional view illustrating a printed circuit board 1000′ having an Embedded Trace Substrate (ETS) structure.

Referring to FIG. 21, a side surface of a first pad 202′ and a side surface of a second pad 204′ may be embedded in an insulating layer 100′, respectively, and at least a portion of an upper surface of the first pad 202′ and at least a portion of an upper surface of the second pad 204′ may not be embedded in the insulating layer 100′. Accordingly, the thickness of the printed circuit board 1000 is reduced, and the area of the pad exposed to the outside is reduced, thereby further improving structural stability.

At least a portion of the upper surface of the first pad 202′ and at least a portion of the upper surface of the second pad 204′ may be exposed to an upper surface of the insulating layer 100′, respectively. For example, a protruding pattern 206′ may be disposed on at least a portion of the upper surface of the exposed first pad 202′. For example, at least a portion of the upper surface of the second pad 204′ may be exposed to the outside through the second opening OP2.

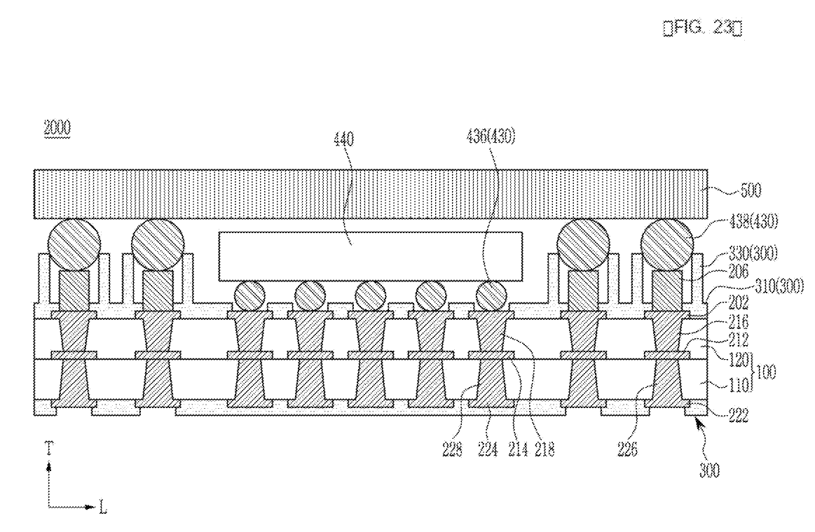

FIG. 22 is a cross-sectional view illustrating an electronic component package according to an embodiment.

Referring to FIG. 22, an electronic component package 2000 may include the above-described printed circuit board 1000 and electronic components 400 mounted on the printed circuit board 1000.

In one example, the electronic components 400 may include a first electronic component 410 connected to the first pad 202 through the protruding pattern 206, and a second electronic component 420 connected to the second pad 204.

In the thickness direction, a length of the first electronic component 410 may be smaller than a length of the second electronic component 420. Through the protruding pattern 206 and the wall pattern 330, a step difference between the electronic components 410 and 420 having different sizes may be substantially removed or reduced. Accordingly, structural stability and space utilization of the electronic component package 2000 may be improved, and warpage and/or distortion of the printed circuit board 1000 may be prevented.

The electronic components 400 may be mounted on the printed circuit board 1000 through the solder 430. The first electronic component 410 may be electrically connected to the protruding pattern 206 through a first solder 432. The second electronic component 420 may be electrically connected to the second pad 204 through a second solder 434. The first solder 432 may be in contact with the protruding pattern 206 and the first electronic component 410, and the second solder 434 may be in contact with the second pad 204 and the second electronic component 420. In an example, the diameter or length of the long axis of the first solder 432 may be greater than the diameter or length of the long axis of the second solder 434. Accordingly, the height difference between the electronic components 410 and 420 having different sizes may be further mitigated.

According to an example, a ratio (L5/L4) of a length L5 from the upper surface of the insulating layer 100 to the upper surface of the second electronic component 420 in the thickness direction to a length L4 from the upper surface of the insulating layer 100 to the upper surface of the first electronic component 410 in a thickness direction may be 0.9 to 1.1. In the above range, structural stability and space utilization of the electronic component package 2000 may be further improved, and warpage and/or distortion of the printed circuit board 1000 may be sufficiently prevented.

An absolute value of the difference between L4 and L5 may be less than 5.0 mm and may be 0.1 mm to 3.0 mm. Within the above range, the above-described structural stability and space utilization may be further improved.

In an example, L5/L4 may be substantially 1.

FIG. 23 is a cross-sectional view illustrating an electronic component package according to another embodiment.

Referring to FIG. 23, a third electronic component 440 and an interposer substrate 500 may be mounted on the above-described printed circuit board 1000.

For example, the third electronic component 440 may be an application processor (AP).

The third electronic component 440 may be electrically connected to the second pad 204 through a third solder 436. The third solder 436 may be in contact with the second pad 204 and the third electronic component 440.

The interposer substrate 500 may be mounted on the printed circuit board 1000 through the protruding pattern 206 and a fourth solder 438. For example, the third electronic component 440 may be disposed between the interposer substrate 500 and the printed circuit board 1000. The fourth solder 438 may be in contact with the protruding pattern 206 and the interposer substrate 500.

What is claimed is:

1. A printed circuit board comprising:
an insulating layer;
a first pad disposed at the insulating layer;
a second pad disposed at the insulating layer and spaced apart from the first pad;
a protruding pattern disposed on an upper surface of the first pad ; and
a solder resist layer disposed on an upper surface of the insulating layer and comprising a first opening exposing the protruding pattern and a second opening exposing at least a portion of the second pad,
wherein the solder resist layer comprises a wall pattern spaced apart from the protruding pattern and surrounding a side surface of the protruding pattern.

2. The printed circuit board of claim 1, wherein
a length from the upper surface of the insulating layer to an upper surface of the wall pattern in a thickness direction perpendicular to the upper surface of the insulating layer is equal to or greater than a length from the upper surface of the insulating layer to an upper surface of the protruding pattern.

3. The printed circuit board of claim 1, wherein
a side surface of the first pad and a side surface of the second pad are disposed on the upper surface of the insulating layer.

4. The printed circuit board of claim 1, wherein
a side surface of the first pad and a side surface of the second pad are embedded in the insulating layer, and at least a portion of the upper surface of the first pad and at least a portion of an upper surface of the second pad are not embedded in the insulating layer.

5. The printed circuit board of claim 1, wherein
a length from the upper surface of the insulating layer to an upper surface of the protruding pattern in a thickness direction perpendicular to the upper surface of the insulating layer is greater than a length from the upper surface of the insulating layer to an upper surface of the second pad.

6. The printed circuit board of claim 1, wherein
the protruding pattern includes a plurality of protruding pattens, and
the wall pattern surrounds the plurality of protruding patterns together.

7. The printed circuit board of claim 1, wherein
a width of the protruding pattern is smaller than a width of the first pad.

8. The printed circuit board of claim 1, further comprising
a plurality of sub-insulating layers comprised in the insulating layer, circuit wirings and connection pads disposed between the plurality of sub-insulating layers, and a via penetrating at least a portion of the plurality of sub-insulating layers to be connected to the connection pads.

9. The printed circuit board of claim 8, wherein
the first pad and the second pad are connected to the connection pads and the circuit wirings through the via.

10. A method of manufacturing a printed circuit board comprising:
forming a build-up structure comprising: an insulating layer, circuit wirings, and connection pads disposed on the insulating layer on a carrier substrate,
separating the build-up structure from the carrier substrate,
forming a first pad at the insulating layer,
forming a second pad disposed at the insulating layer and spaced apart from the first pad,
forming a protruding pattern disposed on the first pad, and
forming a solder resist layer comprising a first opening exposing the protruding pattern, a second opening exposing at least a portion of the second pad, and wall pattern spaced apart from the protruding pattern and surrounding a side surface of the protruding pattern on an upper surface of the insulating layer.

11. The method of claim 10, wherein the forming of the first pad and the second pad comprises
forming via holes in the insulating layer, and
forming the first pad, the second pad, and vias connecting the first pad and the second pad to the connection pads, respectively, through a plating process in the via holes.

12. The method of claim 11, wherein
the protruding pattern is formed on the first pad through a plating process.

13. The method of claim 10, wherein the forming of the solder resist layer comprises:
applying a solder resist on the upper surface of the insulating layer,
first thinning the solder resist to form the first opening and the wall pattern, and
second thinning the solder resist to form the solder resist layer comprising the second opening.

14. The method of claim 10, wherein the forming of the solder resist layer comprises
forming a first solder resist layer comprising the second opening, and
forming a second solder resist layer comprising the wall pattern and the first opening on the first solder resist layer.

15. The method of claim 10, wherein
the forming of the first pad and the second pad further comprises forming a via connecting the first pad and the second pad to the circuit wirings respectively.

16. An electronic component package comprising;
the printed circuit board of claim 1;
a first electronic component connecting to the protruding pattern; and
a second electronic component connecting to the second pad.

17. The electronic component package of claim 16, wherein
a ratio of a length from the upper surface of the insulating layer to an upper surface of the second electronic component in the thickness direction to a length from the upper surface of the insulating layer to an upper surface of the first electronic component in a thickness direction is 0.9 to 1.1.
